(19) United States
(12) Patent Application Publication
(10) Pub. No.: US 2024/0057381 A1
(43) Pub. Date: Feb. 15, 2024

(54) STRUCTURE OF PIXEL LAYOUT AND ELECTROLUMINESCENT DISPLAY

(71) Applicant: ULTRADISPLAY INC., Zhubei City (TW)

(72) Inventors: Shih-Song CHENG, Zhubei City (TW); Sen-Chuan HUNG, Zhubei City (TW)

(73) Assignee: ULTRADISPLAY INC., Zhubei City (TW)

(21) Appl. No.: 18/230,324

(22) Filed: Aug. 4, 2023

(30) Foreign Application Priority Data
Aug. 12, 2022 (TW) 111130369

(51) Int. Cl. H10K 59/121; H10K 59/131

(52) U.S. Cl. CPC H10K 59/1213; H10K 59/1216; H10K 59/131

(57) ABSTRACT

Embodiments of the present disclosure provide a structure of pixel layout and an electroluminescent display, wherein there is at least one pixel unit including the structure of pixel layout in the electroluminescent display. The structure of pixel layout includes a high-voltage device area, a low-voltage device area, and a transition area. The first type of high-voltage transistor and the capacitor of the transition area share the second type of well contact, and the second type of low-voltage transistor in the low-voltage device area includes a first type of well contact coupled to an intermediate voltage terminal. With such configuration, the operating voltage of each device may be adjusted so that the pixel circuit can operate normally in a limited layout area of a subpixel, and the problem that the pixel density cannot be improved is solved.

### CROSS-REFERENCE TO RELATED DISCLOSURES

This disclosure claims priority to Taiwan Patent Disclosure No. 11130369, filed Aug. 12, 2022, entitled “structure of pixel layout and electroluminescent display”, which is hereby incorporated by reference in its entirety.

### TECHNICAL FIELD

The present disclosure relates to the field of pixel layout, in particular to a structure of pixel layout for a electroluminescent display.

### BACKGROUND

An electroluminescence display uses light Emitting Diode (LED) or Organic Light Emitting Diode (OLED) as a light-emitting device, and is widely used in consumer and industrial fields nowadays. The improving of display quality is an important and continuous target in developing display technique. No matter the driving substrate of a display uses the Thin Film Transistor (TFT) process used in a traditional display or uses the CMOS (Complementary Metal-Oxide-Semiconductor) process used in a micro display, a specification of pixels per inch (PPI) becomes one of the most important focuses.

Although the CMOS process may greatly improve the specification of PPI, in the current display made under the nano technology node or advanced technology node, high-voltage devices and low-voltage devices cannot be placed in a limited area of subpixel layout due to the limitation on the devices used to consist a pixel circuit by the process and design rules, which applies limitation on the pixel density of such displays and thus the pixel density of such displays cannot be increased.

### BRIEF SUMMARY

Aspects of the present disclosure provides a structure of pixel layout and an electroluminescent display, so that high-voltage devices and low-voltage devices may be placed in a limited area of subpixel layout at the same time, and the problems that on the Pixels Per Inch, PPI of such displays cannot be increased due to the limitation thereon can be solved.

An embodiment of the present disclosure provides a structure of pixel layout for being used in a pixel unit. The structure of pixel layout includes a transition area, a high-voltage device area, and a low-voltage device area. The transition area is provided with a second type of well contact. The second type of well contact is coupled to a first voltage terminal, and electrically provided with a capacitor. The high-voltage device area is located on a side within the pixel unit, and electrically provided with a first type of high-voltage transistor and an electroluminescent device. The first type of high-voltage transistor and the capacitor share the second type of well contact, and the electroluminescent device is coupled to the first type of high-voltage transistor and a second voltage terminal, respectively. Particularly, one of the first voltage terminal and the second voltage terminal has the highest driving voltage, and the other has the lowest driving voltage. The low-voltage device area is located on a side away from the high-voltage device area in the pixel unit, and the transition area is between the high-voltage device area and the low-voltage device area. The low-voltage device area is electrically provided with a second type of low-voltage transistor, and the second type of low-voltage transistor includes a first type of well contact coupled to the intermediate voltage terminal. Particularly, the intermediate voltage terminal is used to provide an intermediate voltage, the intermediate voltage is between the highest driving voltage and the lowest driving voltage.

In an embodiment of the present disclosure, the low-voltage device area is further electrically provided with a first type of low-voltage transistor, the first type of low-voltage transistor and the capacitor, the first type of high-voltage transistor share the second type of well contact.

In an embodiment of the present disclosure, the structure of pixel layout further includes an insulating layer extending from the high-voltage device area to the low-voltage device area, and having a first thickness in the high-voltage device area, a second thickness in the low-voltage device area, and a thickness gradient in the transition area, the first thickness is greater than the second thickness, and the thickness gradient decreases from a side of the high-voltage device area towards a side of the low-voltage device area.

In an embodiment of the present disclosure, the capacitor is located on a side of the thickness gradient close to the high-voltage device area, a side of the thickness gradient close to the low-voltage device area, or on the thickness gradient.

In an embodiment of the present disclosure, the structure of pixel layout further includes a first type of substrate. The first type of substrate has a second type of well, the second type of well encompasses the high-voltage device area, the transition area, and a part of the low-voltage device area, and the second type of well contact is located in the second type of well.

In an embodiment of the present disclosure, the structure of pixel layout has a first boundary and a second boundary in a length direction, and has a first predetermined distance between the first boundary and the second boundary; and has a third boundary and a fourth boundary in a width direction, and has a second predetermined distance between the third boundary and the fourth boundary, the first predetermined distance and the second predetermined distance are not greater than 10 microns. Particularly, the high-voltage device area is configured as being towards the second boundary along the first boundary, and the low-voltage device area is configured as being towards the first boundary along the second boundary.

An embodiment of the present disclosure provides an electroluminescent display including a plurality of pixel units arranged in an array, and at least one pixel unit includes a structure of pixel layout. The structure of pixel layout includes a high-voltage device area, a low-voltage device area, and a transition area between the high-voltage device area and the low-voltage device area. The transition area is provided with a second type of well contact. The second type of well contact is coupled to a first voltage terminal, and electrically provided with a capacitor. The high-voltage device area is located on a side within the pixel unit, and electrically provided with a first type of high-voltage transistor and an electroluminescent device. The first type of high-voltage transistor and the capacitor share the second type of well contact, and the electroluminescent device is coupled to the first type of high-voltage transistor and a second voltage terminal, respectively. Particularly, one of the first voltage terminal and the second voltage terminal has the highest driving voltage, and the other has the lowest driving voltage. The low-voltage device area is located on a side away from the high-voltage device area in the pixel unit, and electrically provided with a second type of low-voltage transistor, and the second type of low-voltage transistor includes a first type of well contact coupled to the intermediate voltage terminal. Particularly, the intermediate voltage terminal is used to provide an intermediate voltage, the intermediate voltage is between the highest driving voltage and the lowest driving voltage.

The structure of pixel layout provided by embodiments of the present disclosure disposes an intermediate voltage terminal in the low-voltage device area to provide an intermediate voltage between the highest and lowest driving voltage used by a pixel unit to set an operating voltage of the second type of low-voltage transistor. At the same time, with the capacitor and the high-voltage device sharing the second type of well contact as a way to configure the body, when the structure of pixel layout is applied to an electroluminescent display, the high-voltage devices and low-voltage devices can be configured in a pixel unit or a sub-pixel unit with a limited area at the same time, so as to reduce the layout area that the transistor must occupy, and it is easier to make implementation in a layout area equal to or less than 10 microns by 10 microns, so that the number of pixel units or sub-pixel units configurable in a electroluminescent display increases, and the pixel density can be specifically increased.

### BRIEF DESCRIPTION OF THE DRAWINGS

The drawings described herein are intended to provide a further understanding of the present disclosure, forming part of the present disclosure, and the schematic embodiments of the present disclosure and its description are used to interpret the present disclosure and do not constitute an improper limitation of the present disclosure. It should be noted that, in accordance with standard practice in the art, the features in the diagram are not drawn to scale. In fact, the size of certain features may be deliberately enlarged or reduced in order to be able to describe them clearly. In the drawings:

FIG. 1 is a plane view of the structure of pixel layout of an embodiment of the present disclosure.

FIG. 2a is a cross-sectional view of the structure of pixel layout of an embodiment of the present disclosure.

FIG. 2b is a cross-sectional view of the structure of pixel layout of some embodiments of the present disclosure.

FIG. 3 is a circuit diagram of the structure of pixel layout of an embodiment of the present disclosure.

FIG. 4 shows a circuit diagram of the equivalent circuit of the circuit diagram in FIG. 3.

### DETAILED DESCRIPTION

Hereinafter, the present disclosure will be described in detail with reference to the accompanying drawings along with illustrated embodiments, so as to better clarify the object, technical solution and advantageous of the present disclosure. It can be conceivable that such descriptions are merely exemplary and are not intended to limit the present disclosure.

Transistors used in all embodiments of the present disclosure may be thin-film transistors (TFT) or field-effect transistors (FET) or other devices with the same characteristics, such as metal-oxide-semiconductor (MOS) transistor. In embodiments of the present disclosure, in order to distinguish the two electrodes of the transistor other than the gate electrode, one of the two electrodes may be referred as the first electrode, and the other electrode may be referred as the second electrode. One skilled in the art would understand that the drain electrode and source electrode of the transistor are interchangeable, depending on the voltage level applied thereto. Therefore, in practical operations, the first electrode may be the drain electrode, and the second electrode may be the source electrode; alternatively, the first electrode may be the source electrode, and the second electrode may be the drain electrode.

Further, it should be understood that if one device is described as being “connected to” or “coupled to” another device, these two devices may be directly connected or coupled to each other, or there may be other intervening device therebetween.

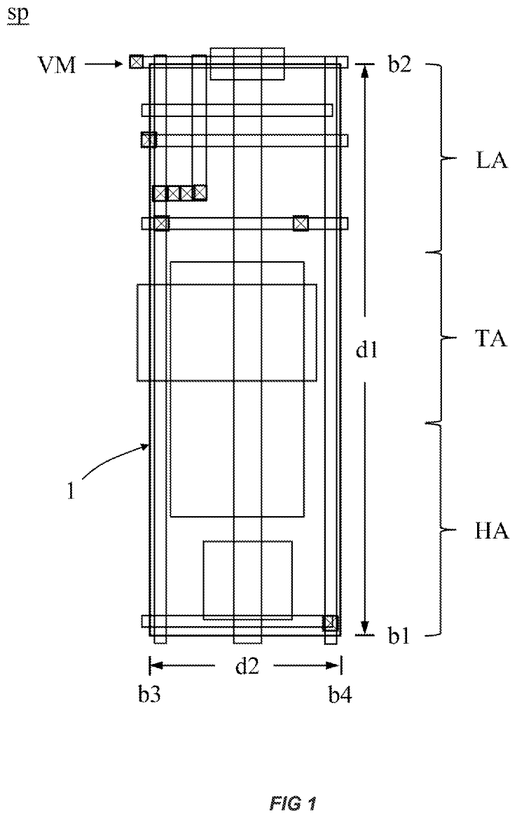

Reference is now made to FIG. 1. An embodiment of the present disclosure provides a structure of pixel layout 1, which may be used in a pixel unit or subpixel unit sp of an electroluminescent display. In the following embodiment, the subpixel unit sp is used as an example for explanation, but the present disclosure is not limited to this.

The structure of pixel layout 1 of the embodiment of the present disclosure has a first boundary b1 and a second boundary b2 in a length direction, and there is a first predetermined distance d1 between the first boundary b1 and the second boundary b2. And, the structure of pixel layout 1 has a third boundary b3 and a fourth boundary b4 in a width direction, and there is a second predetermined distance d2 between the third boundary b3 and the fourth boundary b4. Particularly, the first predetermined distance d1 is not greater than 10 microns, and the second predetermined distance d2 is equal to or less than the first predetermined distance d1.

Wherein, there is a high-voltage device area HA configured towards the second boundary b2 along the first boundary b1 and a low-voltage device area LA configured towards the first boundary b1 along the second boundary b2, in the structure of pixel layout 1, so that the high-voltage device area HA and the low-voltage device area LA are located on the two opposite sides of the structure of pixel layout 1 respectively with a relatively large distance therebetween, and there is a transition area TA between the high-voltage device area HA and the low-voltage device area LA.

Reference is now made to FIG. 1 to FIG. 3. In an embodiment of the present disclosure, the structure of pixel layout 1 includes a first type of substrate 10 and an insulating layer 20. The first type of substrate 10 is doped with a second type of dopant to form a second type of well 110, and the second type of well 110 encompasses the high-voltage device area HA, the transition area TA and part of the low-voltage device area LA. In an embodiment of the present disclosure, the first type is a P type, and the second type is an N type. As an example, the substrate may be a P-substrate and the well may be an N-well, but it is understood that in other embodiments of the present disclosure, the first and second types are interchangeable, and are not limited to the examples of the present embodiment.

The first type of substrate 10 is further configured with a plurality of well contacts, including the first to fifth well contacts 121-125, and the sixth to eighth well contacts 131-133, wherein the first to fifth well contacts 121-125 may be the first type of well contacts, such as P-well contacts, and the sixth to eighth well contacts 131-133 may be the second type of well contacts, such as N-well contacts. The first well contact 121 and the second well contact 122 are configured in the second type of well 110 in the high-voltage device area HA. The third well contact 123 and the fourth well contact 124 are configured in the second type of well 110 in the low-voltage device area LA. The fifth well contact 125 is configured in the first type of substrate 10 in the low-voltage device area LA, and coupled to an intermediate voltage terminal VM. The sixth well contact 131 is configured in the second type of well 110 in the transition area TA, and is coupled to a first voltage terminal VDD, while the seventh well contact 132 and the eighth well contact 133 are configured in the low-voltage device area LA in the first type of substrate 10.

The insulating layer 20 is disposed on the first type of substrate 10, and extends from the high-voltage device area HA to the low-voltage device area LA. The insulation layer 20 has a first thickness t1 in the high-voltage device area HA and a second thickness t2 in the low-voltage device area LA, wherein the first thickness t1 is greater than the second thickness t2, and the transition area TA forms a slope structure G with a thickness gradient decreasing from a side of the high-voltage device area HA towards a side of the low-voltage device area LA.

In addition, an electrode layer 30 is further provided on the insulating layer 20. The electrode layer 30 includes a first electrode 310, a second electrode 320, a third electrode 330 and a fourth electrode 340.

Particularly, the first electrode 310 is electrically provided between the first well contact 121 and the second well contact 122 in the high-voltage device area HA and is used as a gate of a first type of high-voltage transistor HVT, and an electronic channel of a first type of high-voltage transistor HVT is formed between the first well contact 121 and the second well contact 122.

The second electrode 320 is electrically provided above the second type of well 110 in the transition area TA, and is used as an upper electrode of a capacitor C.

The third electrode 330 is electrically provided between the third well contact 123 and the fourth well contact 124 in the low-voltage device area LA, and is used as a gate of a first type of low-voltage transistor LVT1, and an electronic channel of a first type of low-voltage transistor LVT1 is formed between the third well contact 123 and the fourth well contact 124.

The fourth electrode 340 is electrically provided between the seventh well contact 132 and the eighth well contact 133 in the low-voltage device area LA, and is used as a gate of a second type of low-voltage transistor LVT2, and an electronic channel of a second type of low-voltage transistor LVT2 is formed between the seventh well contact 132 and the eighth well contact 133.

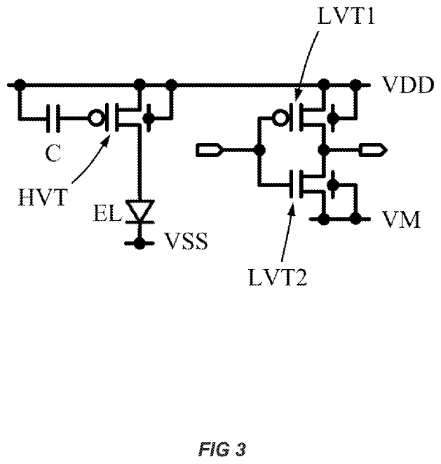

Therefore, in an embodiment of the present disclosure, the high-voltage device area HA of the structure of pixel layout 1 is electrically provided with a first type of high-voltage transistor HVT, the low-voltage device area LA is electrically provided with a first type of low-voltage transistor LVT1 and a second type of low-voltage transistor LVT2, and the transition area TA is electrically provided with a capacitor C, thereby a circuit architecture as shown in FIG. 3 may be implemented.

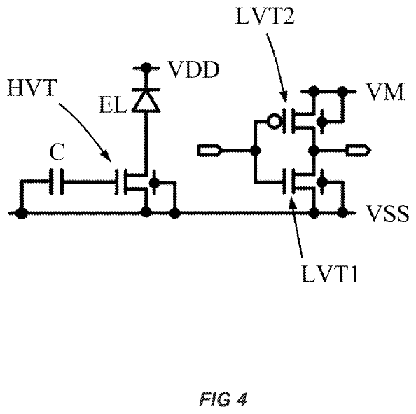

Although in the circuit architecture of FIG. 3, as an example for explanation, the first type of high-voltage transistor HVT is a P-type high-voltage transistor, the first type of low-voltage transistor LVT1 is a P-type low-voltage transistor, and the second type of low-voltage transistor LVT2 is an N-type low-voltage transistor. However, it is understood that in other embodiments of the present disclosure, such circuit may be implemented by an equivalent circuit, in which the first type of high-voltage transistor HVT is an N-type high-voltage transistor, the first type of low-voltage transistor LVT1 is an N-type low-voltage transistor and the second type of low-voltage transistor LVT2 as a P-type low-voltage transistor (as shown in FIG. 4), and thus the present disclosure is not limited to the embodiment.

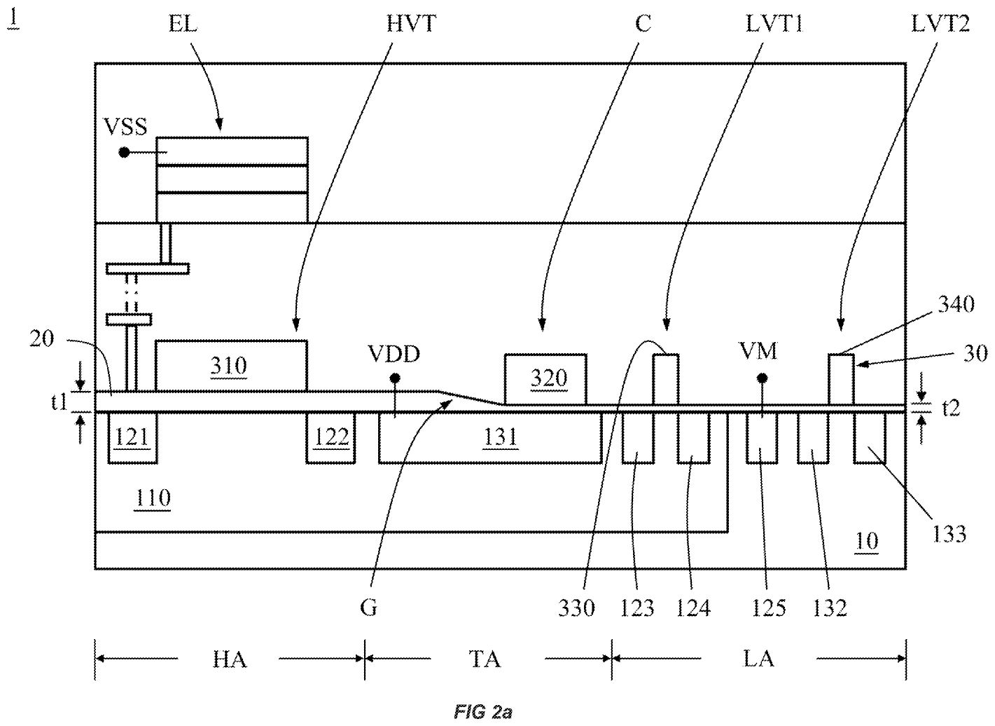

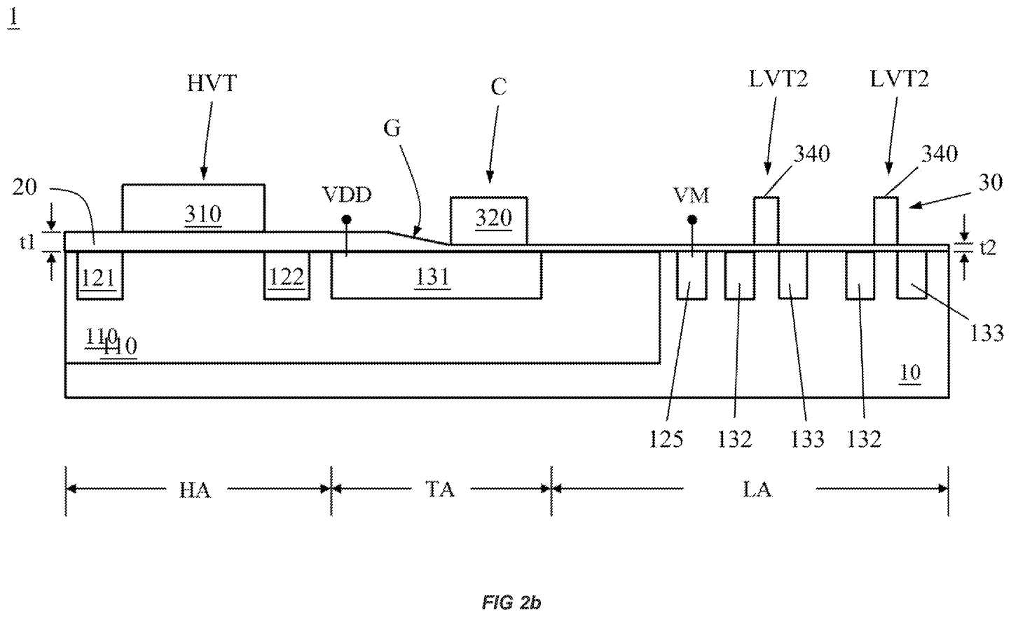

Reference is now made to FIG. 2a to FIG. 3. In an embodiment of the present disclosure, capacitor C is coupled to a first type of high-voltage transistor HVT and/or a first type of low-voltage transistor LVT1, and the capacitor C may be located in the transition area TA on a side of the slope structure G formed by the insulating layer close to the high-voltage device area HA (as shown in FIG. 2a), and configured in the structure of pixel layout 1 in a form of a large capacitor, or located on a side of the slope structure G close to the low-voltage device area LA (as shown in FIG. 2b) or disposed on the slope structure G and is configured in the structure of pixel layout 1 as a small capacitor.

Further, as shown in FIG. 2a, in an embodiment of the present disclosure, an electroluminescent device EL is provided above the first type of high-voltage transistor HVT with one end coupled to the first well contact 121 or the second well contact 122 in the first type of high-voltage transistor HVT, and the other end coupled to a second voltage terminal VSS, so that the electroluminescent device EL may emit light under driving by the first type of high-voltage transistor HVT.

Reference is now made to FIG. 2a and FIG. 3. In an embodiment of the present disclosure, the first voltage terminal VDD has a highest driving voltage, the second voltage terminal VSS has a lowest driving voltage, and the intermediate voltage terminal VM has an intermediate voltage between the highest driving voltage and the lowest driving voltage. Therefore, with the architecture in which the capacitor C, the first type of high-voltage transistor HVT and the first type of low-voltage transistor LVT1 share the body, and the configuration of the second type low-voltage transistor LVT2 being coupled to the intermediate voltage terminal VM, the operating voltage of the second type of low-voltage transistor LVT2 may be set within an operable range, so that the high-voltage device and the low-voltage device may operate normally even with a configuration where the high-voltage device and the low-voltage device are disposed in a limited layout area of the structure of pixel layout at the same time.

Meanwhile, because the first type of high-voltage transistor HVT, the first type of low-voltage transistor LVT2 and the capacitor C share the body, the layout area occupied by the transistor is reduced, and it is easier to dispose more pixel units or sub-pixel units in the limited area of the layout of pixel circuit, so that the number of pixel units or subpixel units configurable in the electroluminescent display increases, thereby greatly improving the overall PPI of the electroluminescent display.

Although the above embodiment is illustrated with an example that the structure of pixel layout 1 includes a first type of high-voltage transistor HVT, a capacitor C, a first type of low-voltage transistor LVT1 and a second type of low-voltage transistor LVT2. However, in some embodiments of the present disclosure, a first type of high-voltage transistor HVT, capacitor C and one or more second type of low-voltage transistors LVT2 may be provided in the structure of pixel layout 1.

For example, as shown in FIG. 2b, a first type of high-voltage transistor HVT is electrically provided in the high-voltage device area HA of structure of pixel layout 1, a capacitor C is electrically provided in the transition area TA, and one or more second type of low-voltage transistors LVT2 are electrically provided in the low-voltage device area LA. Particularly, when there are a plurality of second type of low-voltage transistors LVT2, these second type of low-voltage transistors LVT2 share the fifth well contact 125 as its body.

Similarly, in other embodiments of the present disclosure, a plurality of first type of low voltage transistors may be provided in the low-voltage device area LA, and these first type of low voltage transistors, capacitors C and first type of high voltage transistor HVT share the sixth well contact 131 as its body. With such configuration of well contact being shared as the body, the area occupied by the transistors in the limited layout area of the pixel circuit can be further reduced, and then more pixel units or sub-pixel units can be configured in the electroluminescent display, so that the overall PPI can be improved.

Characteristics of various embodiments summarized above are for better understanding of one skilled in the art on the present disclosure. One skilled in the art should understand that the present disclosure is convenient to be used as a basis of designing or modifying other processes and structures to implement the embodiments described in the present disclosure for same objects and/or achieve same advantages. One skilled in the art should also understand that such equivalent constructions are within the spirit and scope of the present disclosure, and various variations, modifications, alternatives can be made thereto without departing from the spirit and scope of the present disclosure.

1. A structure of pixel layout, being used in a pixel unit, the structure of pixel layout comprises:
a transition area, provided with a second type of well contact, the second type of well contact is coupled to a first voltage terminal, and electrically provided with a capacitor;
a high-voltage device area, located on a side within the pixel unit, electrically provided with a first type of high-voltage transistor and an electroluminescent device, the first type of high-voltage transistor and the capacitor share the second type of well contact, the electroluminescent device is coupled to the first type of high-voltage transistor and a second voltage terminal, respectively, wherein one of the first voltage terminal and the second voltage terminal has a highest driving voltage, and the other one has a lowest driving voltage; and
a low-voltage device area, located on a side within the pixel unit away from the high-voltage device area, the transition area is located between the high-voltage device area and the low-voltage device area, the low-voltage device area is electrically provided with a second type of low-voltage transistor, and the second type of low-voltage transistor comprises a first type of well contact coupled to an intermediate voltage terminal, wherein the intermediate voltage terminal is used to provide an intermediate voltage, and the intermediate voltage is between the highest driving voltage and the lowest driving voltage.

2. The structure of pixel layout according to claim 1, wherein the low-voltage device area is further electrically provided with a first type of low-voltage transistor, the first type of low-voltage transistor, the capacitor and the first type of high-voltage transistor share the second type of well contact.

3. The structure of pixel layout according to claim 1, further comprises an insulating layer, extending from the high-voltage device area to the low-voltage device area, with a first thickness in the high-voltage device area, a second thickness in the low-voltage device area, and a thickness gradient in the transition area, the first thickness is greater than the second thickness, and the thickness gradient decreases from a side of the high-voltage device area towards a side of the low-voltage device area.

4. The structure of pixel layout according to claim 3, wherein the capacitor is located on a side of the thickness gradient close to the high-voltage device area, a side of the thickness gradient close to the low-voltage device area, or on the thickness gradient.

5. The structure of pixel layout according to claim 1, further comprises a first type of substrate, the first type of substrate has a second type of well provided therein, the second type of well encompasses the high-voltage device area, the transition area and a part of the low-voltage device area, and the second type of well contact is located in the second type of well.

6. The structure of pixel layout according to claim 1, wherein the structure of pixel layout has a first boundary and a second boundary in a length direction, and there is a first predetermined distance between the first boundary and the second boundary; and the structure of pixel layout has a third boundary and a fourth boundary in a width direction, and there is a second predetermined distance between the third boundary and the fourth boundary, the first predetermined distance and the second predetermined distance are not greater than 10 microns, wherein the high-voltage device area is configured as being towards the second boundary along the first boundary, and the low-voltage device area is configured as being towards the first boundary along the second boundary.

7. An electroluminescent display, wherein the electroluminescent display comprises a plurality of pixel units arranged in an array, and at least one pixel unit comprises a structure of pixel layout, the structure of pixel layout comprises:
a transition area, provided with a second type of well contact, the second type of well contact is coupled to a first voltage terminal, and electrically provided with a capacitor;
a high-voltage device area, located on a side within the pixel unit, and electrically provided with a first type of high-voltage transistor and an electroluminescent device, the first type of high-voltage transistor and the capacitor share the second type of well contact, and the electroluminescent device is coupled to the first type of high-voltage transistor and a second voltage terminal, respectively, wherein one of the first voltage terminal and the second voltage terminal has the highest driving voltage, and the other one has the lowest driving voltage; and
a low-voltage device area, located on a side away from the high-voltage device area in the pixel unit, the transition area is located between the high-voltage device area and the low-voltage device area, and the low-voltage device area electrically provided with a second type of low-voltage transistor, and the second type of low-voltage transistor comprises a first type of well contact coupled to an intermediate voltage terminal, wherein the intermediate voltage terminal is used to provide an intermediate voltage, the intermediate voltage is between the highest driving voltage and the lowest driving voltage.

8. The electroluminescent display according to claim 7, wherein the low-voltage device area is further electrically provided with a first type of low-voltage transistor, the first type of low-voltage transistor and the capacitor, the first type of high-voltage transistor share the second type of well contact.

9. The electroluminescent display according to claim 8, wherein the structure of pixel layout further comprises an insulating layer, extending from the high-voltage device area to the low-voltage device area, with a first thickness in the high-voltage device area, a second thickness in the low-voltage device area, and a thickness gradient in the transition area, the first thickness is greater than the second thickness, and the thickness gradient decreases from a side of the high-voltage device area towards a side of the low-voltage device area.

10. The electroluminescent display according to claim 9, wherein the capacitor is located on a side of the thickness gradient close to the high-voltage device area, a side of the thickness gradient close to the low-voltage device area, or on the thickness gradient.

11. The electroluminescent display according to claim 7, wherein the structure of pixel layout further comprises a first type of substrate, the first type of substrate has a second type of well provided therein, the second type of well encompasses the high-voltage device area, the transition area, and a part of the low-voltage device area, and the second type of well contact is located in the second type of well.

12. The electroluminescent display according to claim 7, wherein the structure of pixel layout has a first boundary and a second boundary in a length direction, and there is a first predetermined distance between the first boundary and the second boundary; and the structure of pixel layout has a third boundary and a fourth boundary in a width direction, and there is a second predetermined distance between the third boundary and the fourth boundary, the first predetermined distance and the second predetermined distance are not greater than 10 microns, wherein the high-voltage device area is configured as being towards the second boundary along the first boundary, and the low-voltage device area is configured as being towards the first boundary along the second boundary.
